(19) United States
(12) Patent Application Publication
(10) Pub. No.: US 2003/0055861 A1
(43) Pub. Date: Mar. 20, 2003

(54) Multipler unit in reconfigurable chip

(76) Inventors: Gary N. Lai, Sunnyvale, CA (US); Joshua James Lindner, Malden, MA (US)

Correspondence Address: ROBERT E. KREBS, THELEN REID & PRIEST LLP, P.O. BOX 640640, SAN JOSE, CA, 95164-0640, US

(21) Appl. No.: 09/955,913

(22) Filed: Sep. 18, 2001

(51) Int. Cl. G06F 7/38; H03K 19/177; G06F 7/52

(52) U.S. Cl. 708/620

(57) ABSTRACT

A multiplication block for a reconfigurable chip includes multiple multiplication units and a group of the selectable adder units operably interconnectable with the multiplication units. The adder units can be selectively connected for different configurations. The multiplication block is preferably controlled by an instruction which can put the multiplication block into different configurations.

### BACKGROUND OF THE INVENTION

The present invention concerns reconfigurable logic. Reconfigurable logic is becoming more and more important, especially reconfigurable logic systems which allow for the implementation of algorithms. These systems are often called reconfigurable computing systems. Reconfigurable computing systems are useful in many applications, especially for communications, in which a large amount of processing is required. The reconfigurable computing systems distribute processing all over the chip, rather than focusing the processing at a central processing unit. Typically, reconfigurable functional units, such as data path units, are used throughout the chip to implement different functions. These reconfigurable functional units can implement a variety of required functions.

It is useful to have dedicated units on a reconfigurable chip to do multiplication. Multiplication is relatively expensive to implement using general-purpose reconfigurable functional units. It is desired to have a reconfigurable chip with an improved multiplier unit for use in implementing algorithms on the reconfigurable chip.

### SUMMARY OF THE INVENTION

One embodiment of the present invention comprises a reconfigurable chip in which a multiplication block, including at least one multiplication unit and a group of selectable adder units, operably connected to the multiplication unit, are used. The adder units are selectively connectable in different configuration. The reconfigurable chip preferably includes an interconnect element operatively connected to the multiplication block. The interconnect elements adapted to selectively connect together the multiplication block with other reconfigurable units. Using adder units within the multiplication block adds flexibility to the system of the present invention.

One embodiment of the present invention concerns a multiplication block on a reconfigurable chip including at least one multiplexer, a multiplication unit operatively connected to the input multiplexer, a group of selectable adder units operatively connected to the multiplication unit, and a group of selectable adder units operatively connected to the multiplication unit. The adder units are selectively connected in different manners. An instruction memory storing multiple instructions for the multiplication block is used. The instruction memory allows for the production of instructions which can cause the adder units to be connectable in different manners so the multiplication block can implement different functions.

Another embodiment of the present invention comprises a multiplication block on a reconfigurable chip. The multiplication block including multiple block input multiplexers, at least two multiplication units, each multiplication associated with two multiplication input multiplexers. The multiplication unit multiplexers are operably connected to the multiple block input multiplexers. A group of selectable adder units with associated adder input multiplexers operably connected to the multiplication units are used. The multiplexer units within the multiplication block allow different configurations to be produced, increasing the flexibility of the system of the present invention.

### BRIEF DESCRIPTION OF THE DRAWING FIGURES

FIG. 1 is a diagram of a reconfigurable chip of the embodiment of the present invention.

FIG. 2 is a diagram of the multiplication block of the system of the present invention.

FIG. 3A-31 are illustrations of configurations for the multiplication block of FIG. 2.

FIG. 4 is a diagram of a variable delay unit for use with the system of the present invention.

FIG. 5 is an illustration of the state instruction and instruction memory associated with the multiplier unit.

FIG. 6 is a diagram illustrating the control system for the multiplier unit.

FIG. 7 is a diagram illustrating the connectivity of the multiplier unit with nearby units.

FIG. 8 is a diagram illustrating the connectivity of the multiplier unit with horizontal and vertical connections buses.

FIG. 9 is a diagram illustrating the interconnection of multiplier units, using the horizontal and vertical buses.

FIG. 10 is a diagram illustrating the layout of one embodiment of the multiplier block of the present invention.

FIG. 11 is a diagram of one example of a multiplier unit for use in the multiplier block of the system of the present invention.

FIG. 12 is a diagram of an adder unit using one embodiment of the multiplier block of the present invention.

FIG. 13 is a diagram of a reconfigurable functional unit of one embodiment of the present invention.

### DETAILED DESCRIPTION OF THE INVENTION

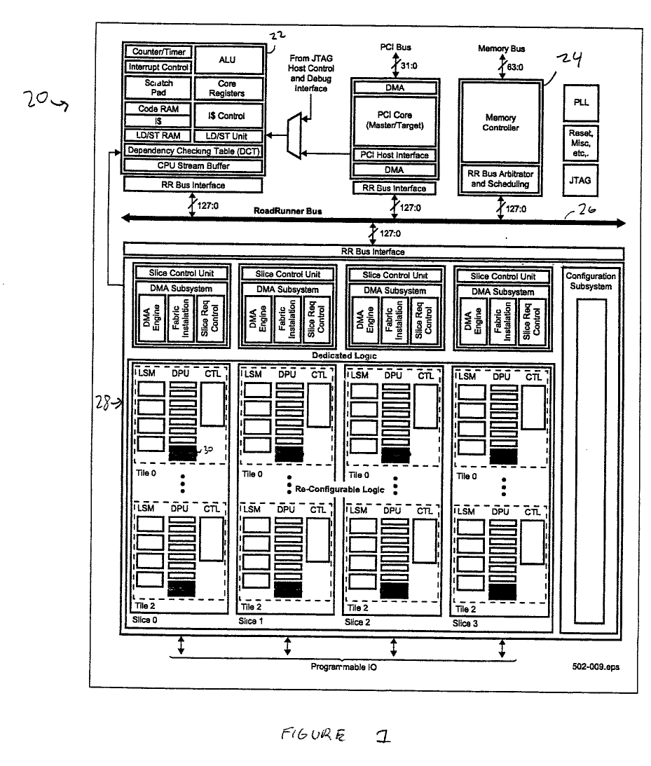

FIG. 1 shows a reconfigurable chip 20. The reconfigurable chip 20 includes a central processing unit 22, a memory controller 24, main bus 26 and a reconfigurable fabric 28. The reconfigurable fabric 28 is preferably divided into a number of different slices. Each of the slices includes a number of different tiles. Note that in one embodiment, each tile contains a multiplier block as described in the present application. In a preferred embodiment, an algorithm, such as a communications algorithm, is implemented by loading different functions into the reconfigurable fabric 28.

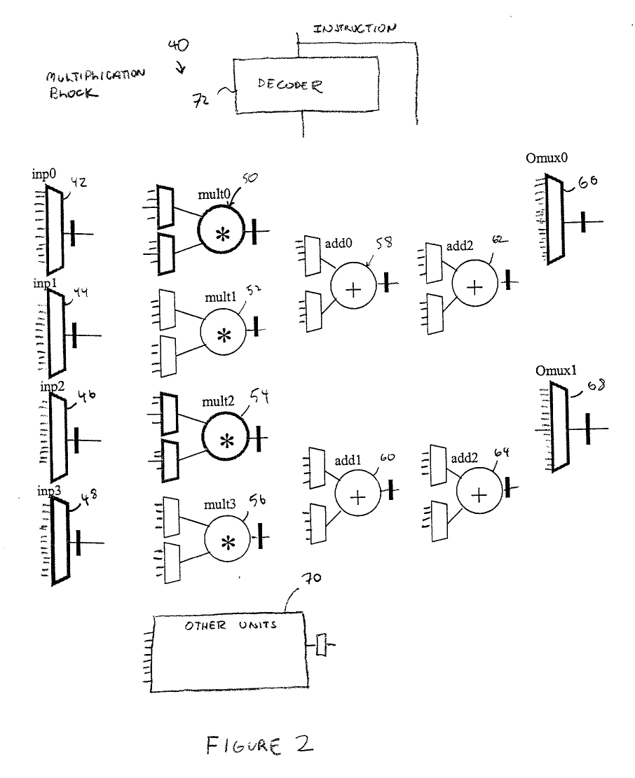

FIG. 2 is a diagram of a multiplication block 40 of one embodiment of the present invention. Shown in the multiplication block 40 are a number of input multiplexers for the blocks 42, 44, 46 and 48. A number of multiplication units, including multiplication unit 50, 52, 54 and 56 are also shown. In addition to the multiplication unit, a number of interconnectable adder units are also shown. These adder units include units 58, 60, 62 and 64. Also used are output multiplexers 66 and 68.

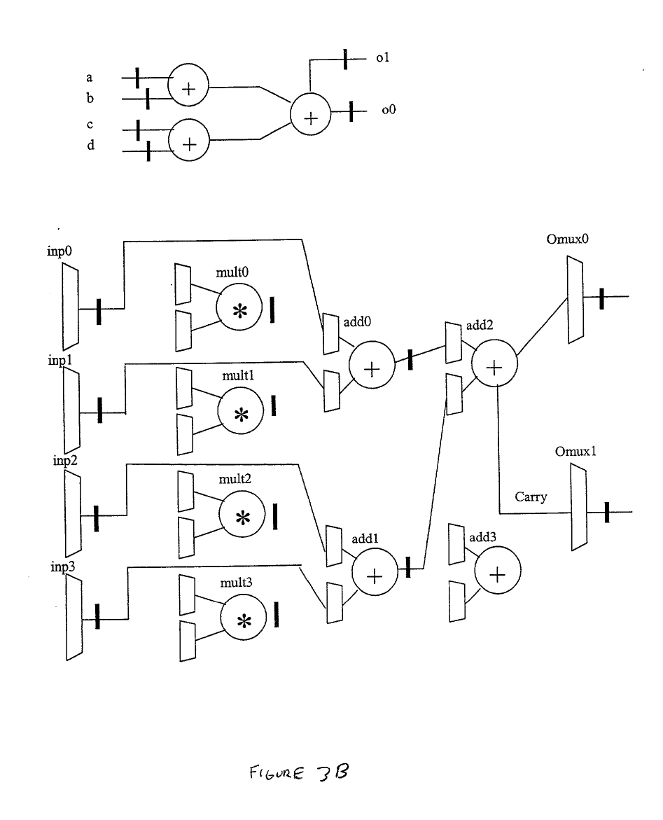

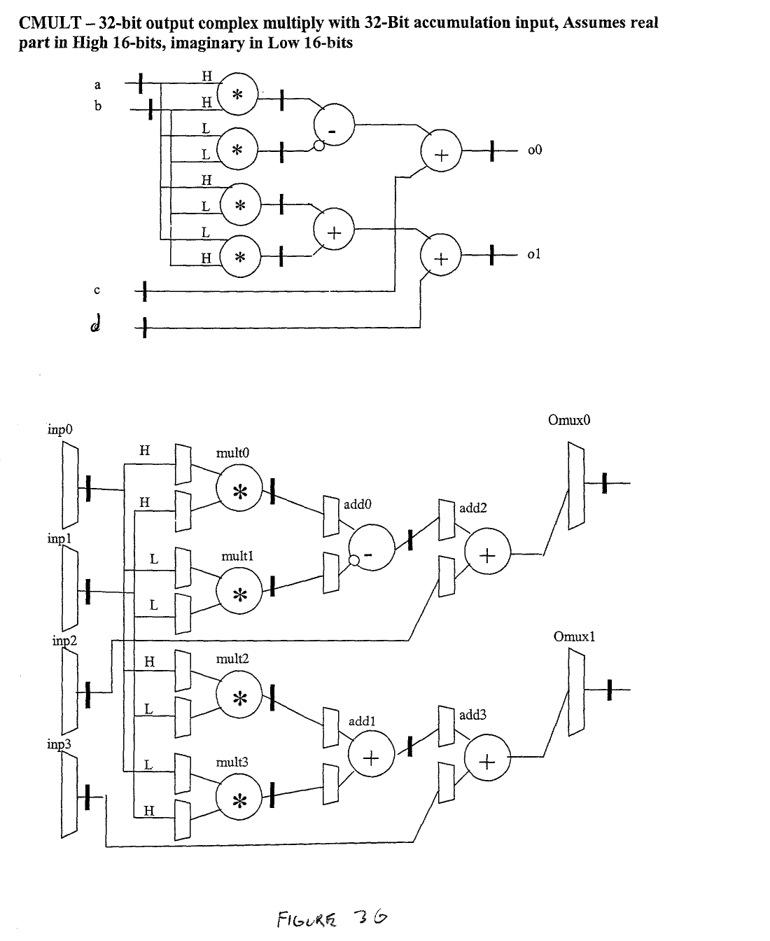

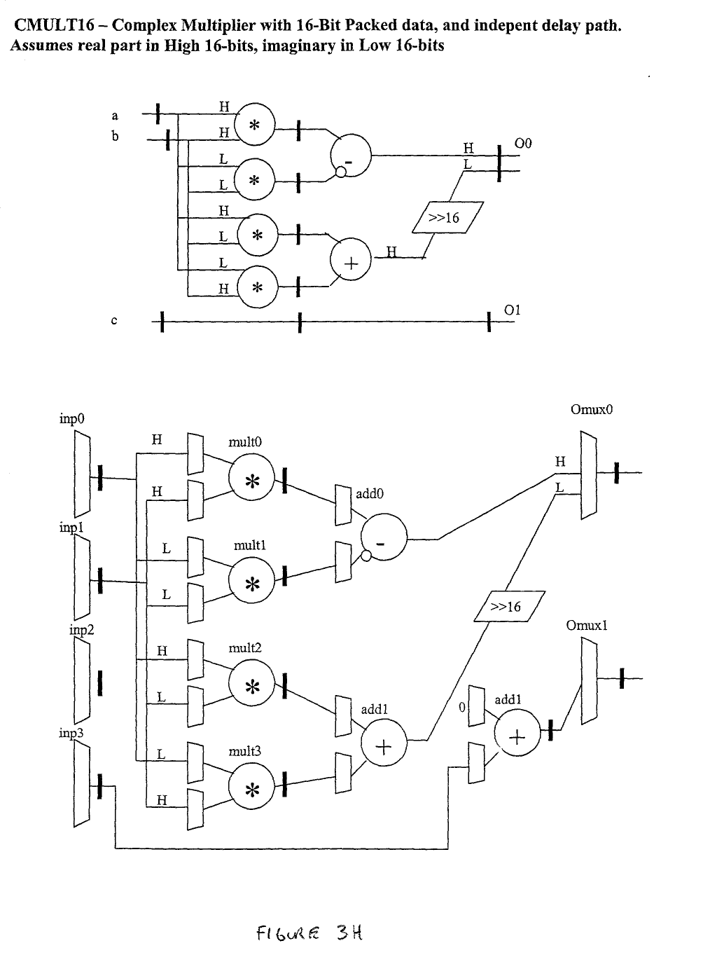

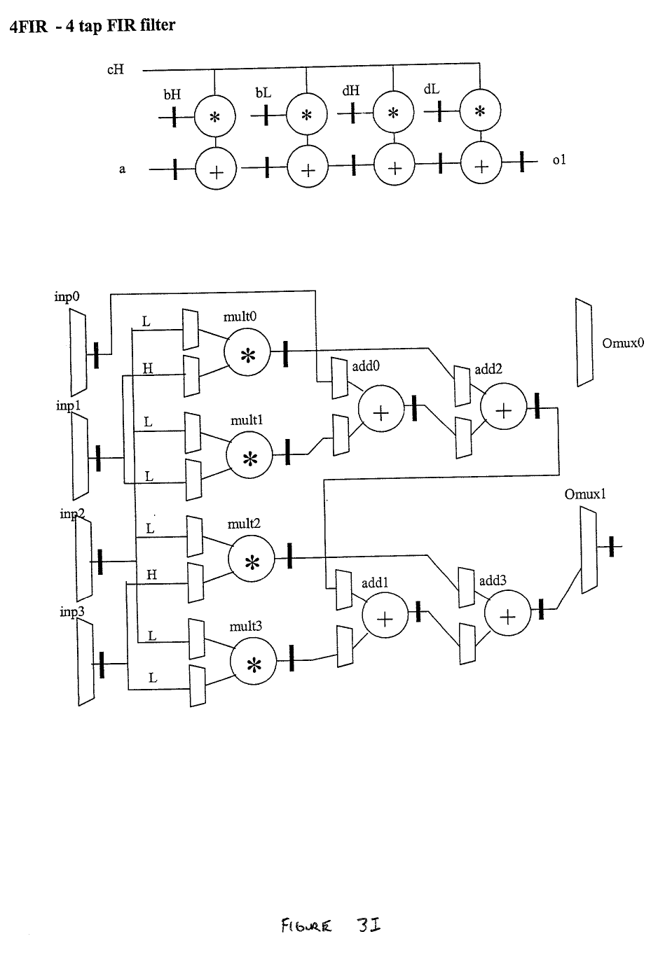

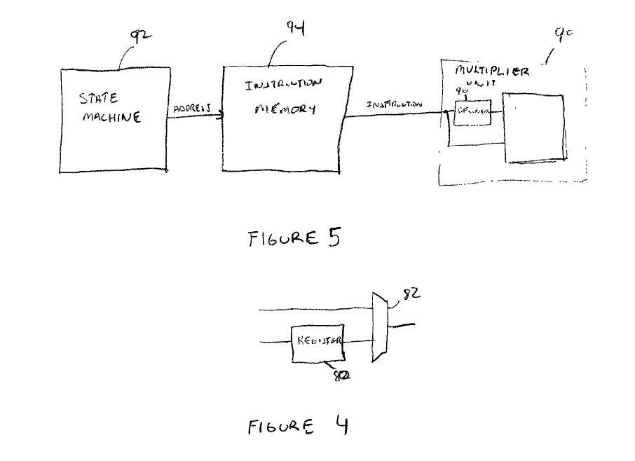

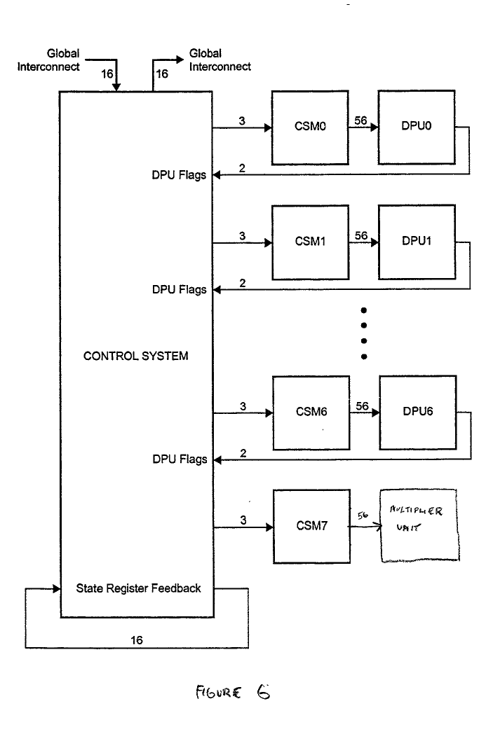

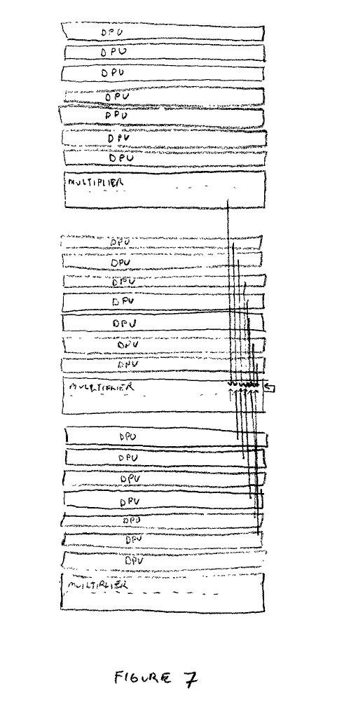

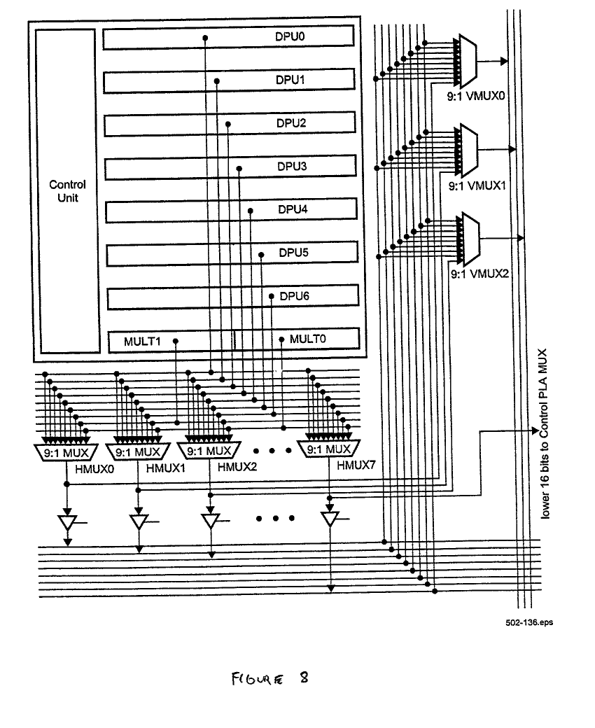

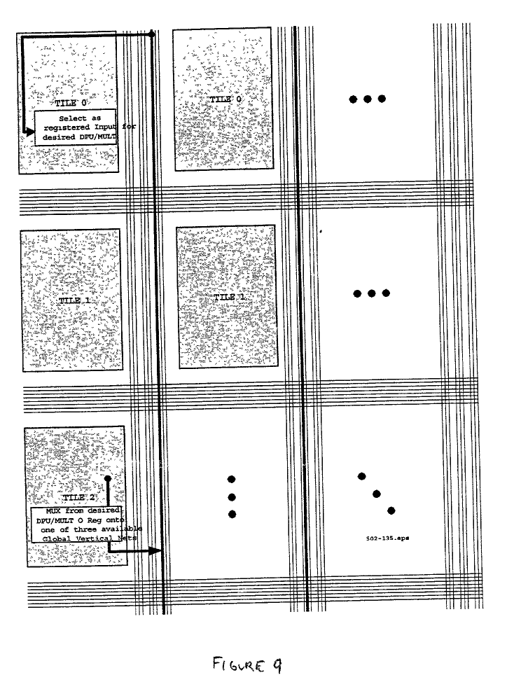

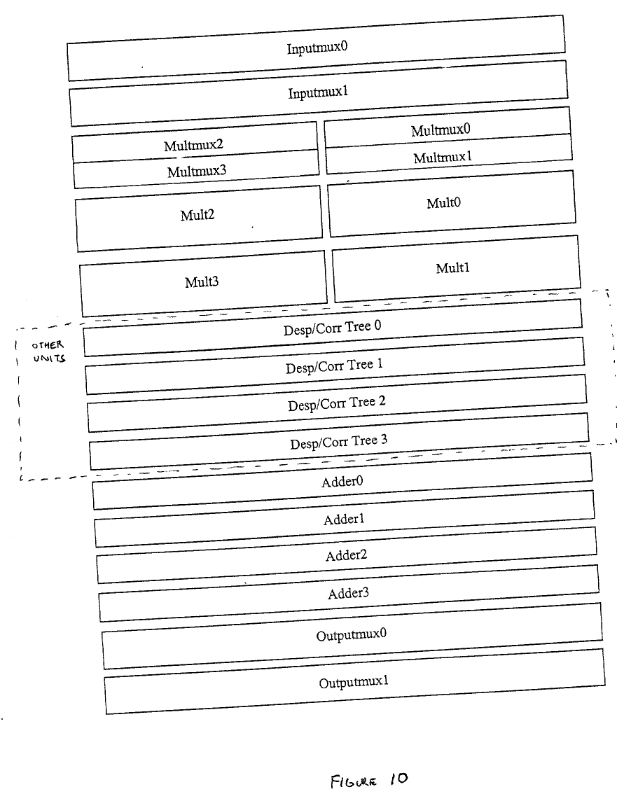

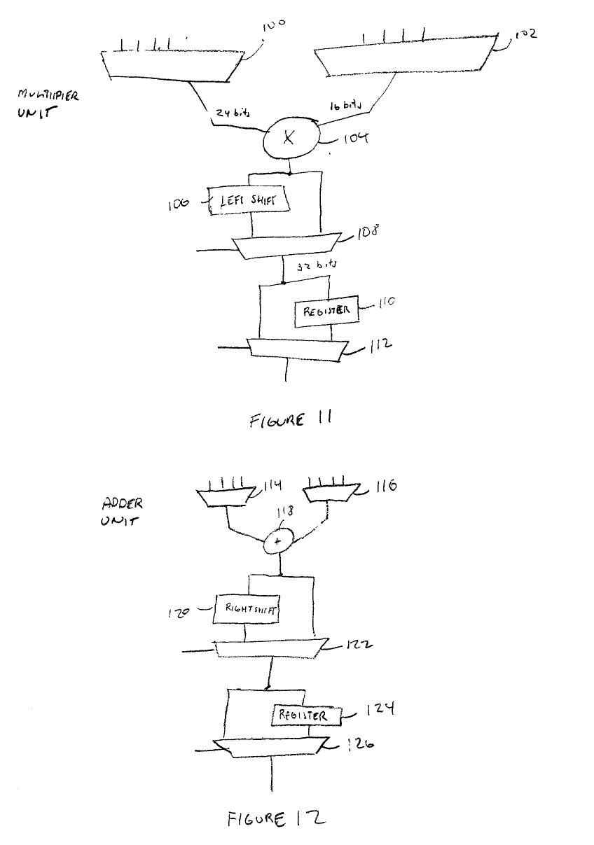

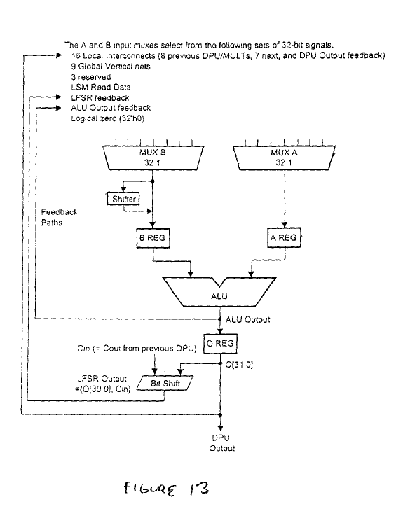

The input multiplexers 42 connect to the horizontal and vertical interconnection buses, as well as nearby units, such as the reconfigurable functional units. The multiplier and adder units each have associated multiplexers. These associated multiplexers allow the multiplier to have large amount of interconnectivity range and quite flexible patterns. For example, the adder blocks can be connected to other adder blocks to multipliers and the like. The outputs of the multiplier and adder blocks are sent to other multiplier and adder block input muxes, as well as to the output muxes of the system, as will be described below with respect to FIG. 3A-31. This system allows great flexibility in the production of functions using the multiplier unit. As will be shown below, regular multiplication can be done as well as additional functionality implemented on the multiplier block unit. Also, other types of units, such as unit 70 can be used. Unit 70 could be, for example, a despeader/correlator system. The despreader/correlator preferably shares the adder system. In a preferred embodiment, when the system uses an adder/correlator, the mulitiplier units are not used. Any other type of unit that would be useful to use the adder units can also be used when the multipliers are needed to be used. The system can use instructions from instruction memory as shown below, with respect to FIG. 5. The multiplication block may or may not use a decoder 72 to produce instructions for the system.

FIG. 3A-31 illustrate different configurations of the system of the present invention. These configurations indicate how, by using the mulitplexers associated with the multiplier units and the adder units are different configurations can be implemented. Note that the system of FIG. 2 includes more multipliers than twice the number of input multiplexers. This allows the relatively complex use of the multipliers of the system of the present invention. A simplified implementation of a multiplier block would have two independent multiplier units each having their own input and output muxes. By having additional multiplier units and adder units, as will be described below, with respect to FIG. 3A-31, the functionality of the system is improved.

FIG. 3A-31 illustrate configurations that can be implemented using the multiplication block of FIG. 2. FIG. 3A illustrates the system in which two independent mulitiplier units are implemented. FIG. 3B illustrates a system in which the multipliers are avoided completely, and sum of 4 32-bit inputs is implemented. FIG. 3C illustrates the system in which the sum of 4 packed 16-bit inputs, and the sum of the upper and lower bits are added together. This illustrates the addition of the sums of the 4 high and 4 low portions of the input signals. FIG. 3D illustrates two different multiplications of the high portion and two different multiplications of the low portion of the input signals. FIG. 3E illustrates the summing of the 4 multipliers of the high and low portions. FIG. 3F illustrates the 2 sums of 2 multipliers. FIG. 3G illustrates 32-bit output complex multiply with 32-bit accumulation input that assumes a real part in the high 16-bits, imaginary in low 16-bits. The inversion of FIG. 3G can be done using a logic at the inputs of the adder units. FIG. 3H illustrates a complex multiplier with 16-bit packed data, and independent data delay. FIG. 3I illustrates an implementation of a 4 tap finite input response (FIR) filter. The configurations of FIG. 3A-31 illustrate a very flexible system.

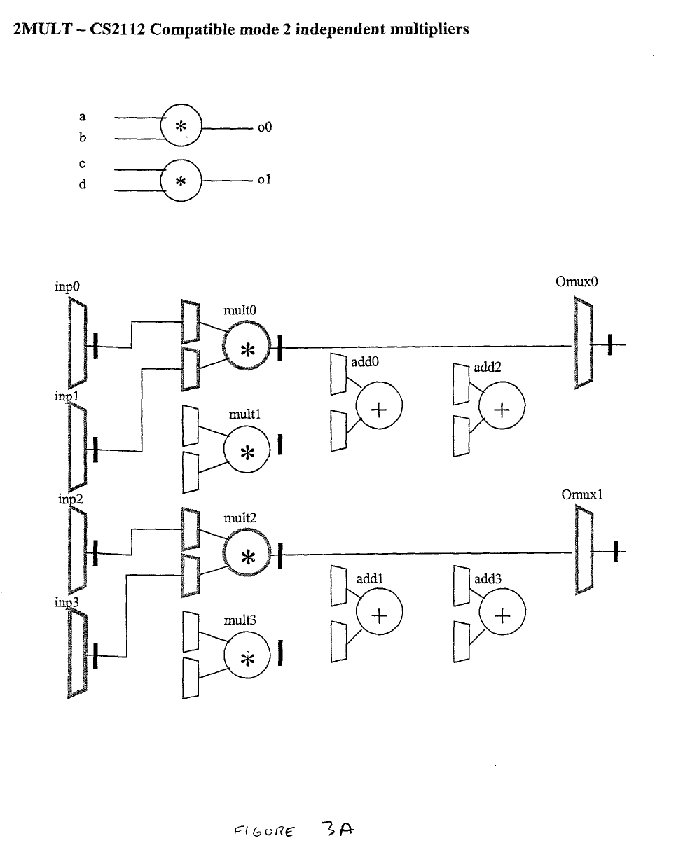

FIG. 4 illustrates a variable delay system in which register 80 is connected to multiplexer 82 to implement a variable delay. Registers can be bypassed by the instructions to the multiplexer 82.

FIG. 5 illustrates the control of the multiplier block 90. State machine 92 provides an address to an instruction memory. The instruction memory provides the instruction to the multiplier unit 90. The instruction can be sent to an optional decoder 96 within the multiplier unit 90. Some or all of the lines in the instruction can thus be decoded to provide the control for the multiplexers within the multiplier unit to provide the configuration for the multiplier unit. In one embodiment, the decoder decodes the 4 to 1 input muxes to the adder and the bypass muxes associated with the register. Other fields that do not need decoding in one embodiment include the multiplier input muxes, the block input muxes and the output muxes. Additionally, the optional shifts and a clock disabled can have their own field and not require a decoder. Other decoder arrangements, using systems without a decoder, can also be used.

FIG. 6 illustrates the control elements for the system of the present invention. In this system, there are control state memories that include the instructions for the multiplier unit, as well as for the data path unit (reconfigurable functional units).

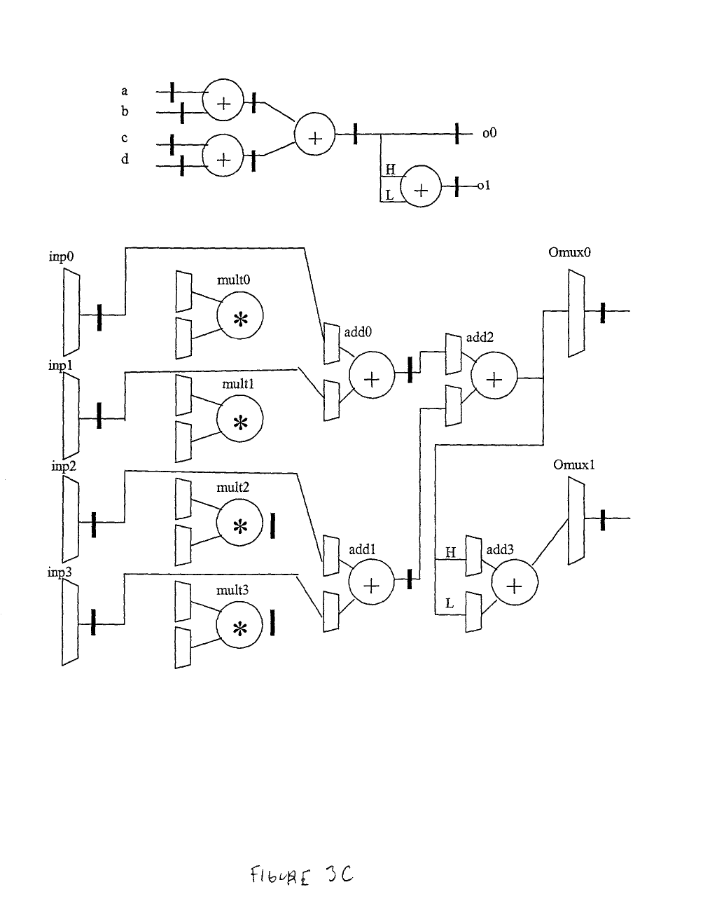

FIG. 7 illustrates the local interconnections of the multiplier unit to nearby elements. In this embodiment, the four input multiplexers are divided into two sets. Each of the two sets are connected to 8 higher units, 7 lower units and itself. This provides good local interconnectivity for the multiplexer unit. FIG. 7 shows the interconnectivity of one set of two input muxes. The other set of two input muxes would connect to another range of local elements.

FIG. 8 illustrates the horizontal and vertical interconnection of the multiplier blocks and the data path units within a tile.

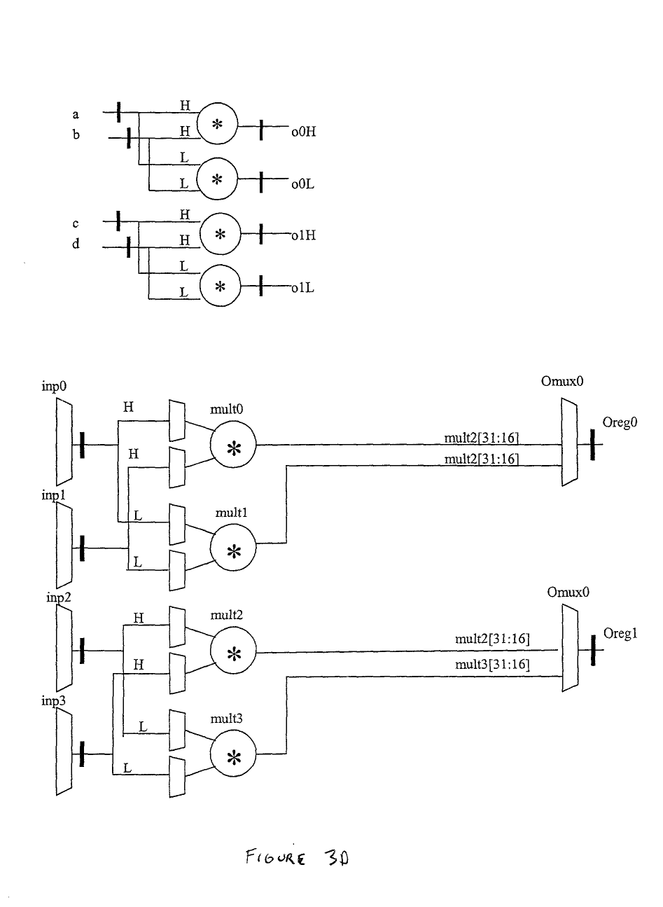

FIG. 9 illustrates the interconnection of elements within a tile, using the horizontal and vertical buses.

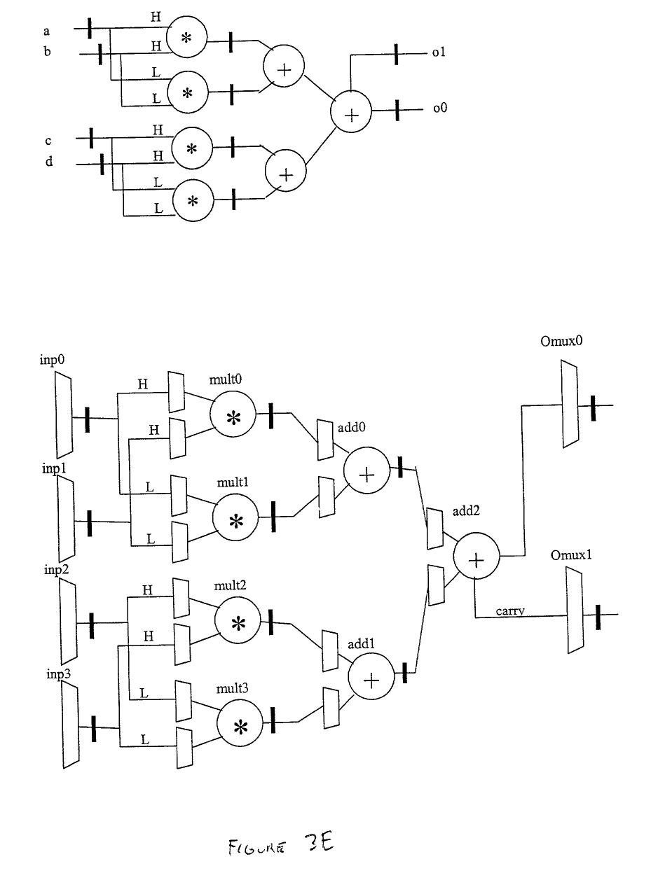

FIG. 10 illustrates a layout for the multiplier blocks of the system of the present invention.

FIG. 11 illustrates a multiplier unit of one embodiment of the present invention. The multiplier unit has associated muxes 100 and 102. This system is implemented using a multiplier that does a 24 bit by 16 bit multiplication. The multiplier unit 104 can be a conventional multiplier. The output of the multiplier 104 can be sent to a left shift unit 106. The left shift unit 106 is preferably a fixed left shift one bit. The left shift unit is useful for certain types of multiplication. Both shifted and unshifted are sent to a multiplexer 108 which selects the desired value. The register 110 is associated with the output of the multiplexer 108. Either this value, or a value from register 110, is selected using the multiplexer 112.

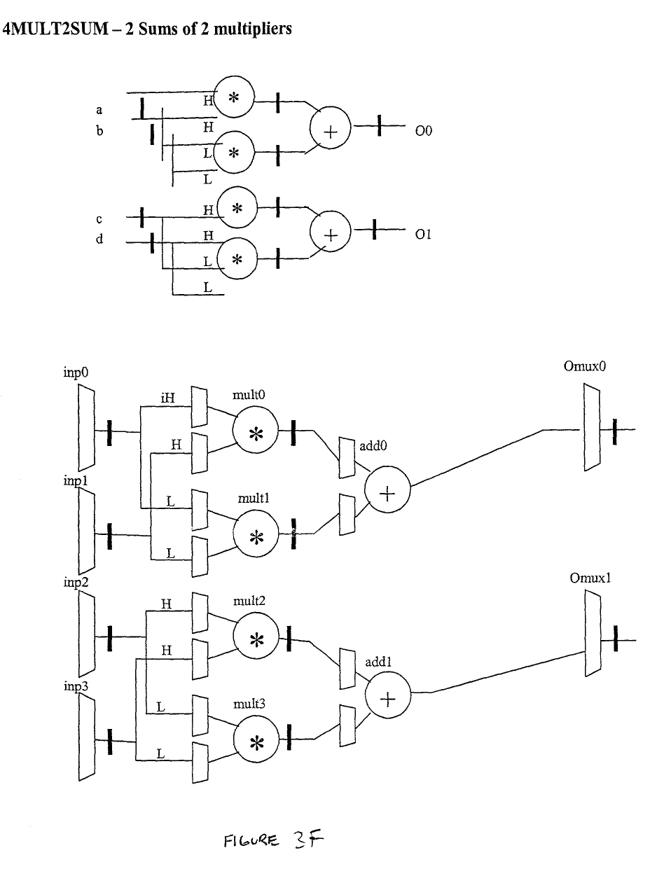

FIG. 12 illustrates an adder unit for the system of the present invention. The adder unit includes an input of muxes 114, 116, conventional adder element 118, a right shift unit 120, the right shift unit can be bypassed using the multiplexer 122. The right shift unit has a similar function as the left shift unit in the multiplier unit of FIG. 11. Looking again at FIG. 12, the value can be sent to a register 124, or the register can be bypassed using the multiplexer 126.

FIG. 13 illustrates a reconfigurable functional unit (data path unit) of one embodiment of the present invention.

Appendix 1 illustrates more information about the multipliers of the present invention.

Appendix 2 illustrates a despreader/correlator system that can be used as an additional element placed within the multiplier block of the present invention.

It will be appreciated by those of ordinary skill in the art that the invention can be implemented in other specific forms without departing from the spirit or character thereof. The presently disclosed embodiments are therefore considered in all respects to be illustrative and not restrictive. The scope of the invention is illustrated by the appended claims rather than the foregoing description, and all changes that come within the meaning and range of equivalents thereof are intended to be embraced herein.

What is claimed is:

1. A reconfigurable chip comprising:
a multiplication block including at least one multiplication unit and a group of selectable adder units operably connected to the multiplication unit, wherein the adder units are selectively connectable in different configurations; and
interconnect elements operably connected to the multiplication block, the interconnect elements adapted to selectively connect together the multiplication block with other reconfigurable units.

2. The reconfigurable chip of claim 1 wherein the multiplication block further comprises input multiplication multiplexers for the block.

3. The reconfigurable chip of claim 2, wherein there are fewer block input multiplexers than input multiplexers for the multiplication units.

4. The reconfigurable chip of claim 1 wherein the adder units include input multiplexers.

5. The reconfigurable chip of claim 1 wherein the multiplication units include input multiplexers.

6. The reconfigurable chip of claim 1 wherein there are multiple multiplication units in each block.

7. The reconfigurable chip of claim 1 wherein the instruction configures the multiplexers in the multiplication block.

8. The reconfigurable chip of claim 1 wherein the multiplication block includes registers associated with the multiplication unit and adder units.

9. The reconfigurable chip of claim 1 wherein the other type of unit is operably connectable to the adder units and can be used instead of multiplier units.

10. The reconfigurable chip of claim 9 wherein the other type of unit comprises the despreader/correlator unit.

11. The reconfigurable chip of claim 1 wherein the adder units can be connected together into chains.

12. The reconfigurable chip of claim 1 wherein the interconnect elements are adapted to transfer word length data.

13. The reconfigurable chip of claim 1 wherein further comprising an instruction memory storing multiple instructions for the reconfigurable functional units.

14. The reconfigurable chip of claim 13 wherein a state machine addresses the instruction memory.

15. The reconfigurable chip of claim 1 wherein the multiplication block includes a selectable output register for the multiplier units and the adder units.

16. The reconfigurable chip of claim 1 wherein the multiplication block includes at least two multiplication units.

17. The reconfigurable chip of claim 1 wherein the multiplication block includes at least four multiplication units.

18. A reconfigurable chip including:
a multiplication block including at least one input multiplexer, a multiplication unit operably connected to the input multiplexer, a group of selectable adder units operably connected to the multiplication unit, wherein the adder units are selectively connectable in different manners; and
an instruction memory storing multiple instructions for the multiplication block.

19. The reconfigurable chip of claim 18 wherein there are input multiplexers for the block.

20. The reconfigurable chip of claim 18 wherein there are input multiplexers associated with the adder units.

21. The reconfigurable chip of claim 18 wherein there are input multiplexers for the multiplication unit.

22. The reconfigurable chip of claim 18 wherein there are fewer block input multiplexers and then input multiplexers for the multiplication units.

23. The reconfigurable chip of claim 18 wherein there are multiple multiplication units in each block.

24. The reconfigurable chip of claim 23, wherein there are at least four multiplication units in each multiplication block.

25. The reconfigurable chip of claim 18 wherein the multiplication block includes a decoder to decode a portion of the instruction.

26. The reconfigurable chip of claim of 18 wherein the multiplication block includes registers associated with the adders units and multiplication units.

27. The reconfigurable chip of claim 26 wherein the registers of selectable output registers.

28. The reconfigurable chip of claim 18 wherein another type of unit is operably connectable to the adders and can be used instead of the multiplier unit.

29. The reconfigurable chip of claim 28 wherein the other type of unit is a despreader/correlator unit.

30. The reconfigurable chip of claim 18 wherein the adder units can be connectable into a chains.

31. The reconfigurable chip of claim 18 further comprising interconnect units operably connected to the multiplication block.

32. The system of claim 18 wherein the instruction memory is addressed by a state machine.

33. A reconfigurable chip including:
a multiplication block including at least one input multiplexer, a multiplication unit operably connected to the input multiplexer, a group of selectable adder units operably connected to the multiplication unit, wherein the adder units are selectively connectable in different manners; and
an instruction memory storing multiple instructions for the multiplication block.

34. The multiplication block of claim 33 wherein there are fewer block input multiplexers than input multiplexers for the multiplication units.

35. The multiplication block of claim 33 wherein there are at least four multiplication units in each multiplication block.

36. The reconfigurable chip of claim 33, wherein there are four multiplication units in each multiplication block.

37. The reconfigurable chip of claim 33 wherein the multiplication blocks are configured by an instruction.

38. The reconfigurable chip of claim 37 wherein at least portions of the instruction is sent to a decoder in the multiplication block.

39. The system of claim 33 wherein the multiplication block includes registers in the multiplication block to store output values.

40. The multiplication block of claim 39 wherein the registers are selectable output registers.

41. The multiplication block of claim 33 wherein there is another type of unit operably connected to the adder units strictly used instead of the multiplier unit.

42. The system of claim 40 wherein the other type of unit comprises a despreader/correlator unit.

43. The multiplication unit block of claim 33 wherein the adder units can be arranged into a chain.

44. The multiplication block of claim 33 further associated with interconnect elements adapted to transfer data between the multiplication block and other local elements.

45. The multiplication block of claim 33 further including an instruction memory storing multiple instructions for the reconfigurable functional units.

46. The multiplication block of claim 45 further comprising a state machine addressing the instruction memory.

47. A multiplication block on a reconfigurable chip, the multiplication block including:
multiple block input multiplexers;
at least two multiplication units, each multiplication unit associated with two multiplication input multiplexers, the multiplication input multiplexers operably connected to the multiple block input multiplexers; and
a group of selectable adder units with associated adder input multiplexers, the adder input multiplexers operably connected to the multiplication units.

48. A reconfigurable chip comprising:
a multiplication block including at least one multiplication unit and a group of selectable adder units operably connected to the multiplication unit, wherein the adder units are selectively connectable in different configurations; and
reconfigurable functional units operably connectable to the multiplication block, the reconfigurable functional units including an arithmetic logic unit and a shifter unit units.
